(19) United States
(12) Patent Application Publication
(10) Pub. No.: US 2026/0175619 A1
(43) Pub. Date: Jun. 25, 2026

(54) WHEEL BEARING ASSEMBLY FOR VEHICLE

(71) Applicant: ILJIN GLOBAL CO.,LTD, Seoul (KR)

(72) Inventors: Hyo Jung YOON, Seoul (KR); Seong Kyu JIN, Seoul (KR); Adam DMYTRYSZYN, Schweinfurt (DE); Tristan HOHMANN, Schweinfurt (DE)

(73) Assignee: ILJIN GLOBAL CO.,LTD, Seoul (KR)

(21) Appl. No.: 19/542,986

(22) Filed: Feb. 18, 2026

Related U.S. Application Data
(63) Continuation of application No. PCT/KR2024/016014, filed on Oct. 21, 2024.

(30) Foreign Application Priority Data
Oct. 24, 2023 (KR) 10-2023-0143301

(51) Int. Cl. B60B 27/02; B60B 27/00; F16D 1/06

(52) U.S. Cl. CPC B60B 27/02; B60B 27/0036; B60B 27/0078; F16D 1/06; F16D 2200/0026; F16D 2250/0046

(57) ABSTRACT

Provided is a wheel bearing assembly for rotatably mounting and supporting a wheel of a vehicle on a vehicle body. The wheel bearing assembly includes: a wheel hub to which the wheel of the vehicle is mounted and configured to rotate together with the wheel of the vehicle; at least one inner ring mounted on an outer circumferential surface of the wheel hub in a press-fitting manner; an outer ring mounted on and fixed to a vehicle-body-side member; a plurality of rolling elements configured to rotatably support the wheel hub and the inner ring relative to the outer ring; and a constant velocity joint coupled to the wheel hub. The constant velocity joint may be configured such that an outer axial end surface of a shoulder portion is in contact with an inner axial end surface of the wheel hub or the inner ring.

### CROSS-REFERENCE TO RELATED APPLICATIONS

This application is a continuation of International Application No. PCT/KR2024/016014 filed on Oct. 21, 2024, which claims priority to Korean Patent Application No. 10-2023-0143301 filed on Oct. 24, 2023, the entire contents of which are herein incorporated by reference.

### TECHNICAL FIELD

The present invention relates to a wheel bearing assembly for a vehicle which rotatably mounts and supports a wheel of a vehicle on a vehicle body, and more particularly, to a wheel bearing assembly for a vehicle configured to suppress stick-slip noise from being generated at a contact surface between a wheel bearing and a constant velocity joint by forming a low-friction metal alloy layer on the contact surface between the wheel bearing and the constant velocity joint.

### BACKGROUND ART

A wheel bearing is a device which rotatably mounts and supports a wheel of a vehicle on a vehicle body, and may be classified into a driving wheel bearing for a driving wheel, which is mounted on a driving wheel of a vehicle, and a driven wheel bearing for a driven wheel, which is mounted on a driven wheel of a vehicle.

Referring to FIG. 1, there is exemplarily illustrated a structure of a wheel bearing assembly for a driving wheel (so-called third-generation wheel bearing assembly) used in the related art.

As illustrated in FIG. 1, a wheel bearing assembly 10 is configured such that rotary elements (for example, a wheel hub 20 and an inner ring 30) are connected to a non-rotary element (for example, an outer ring 40) via rolling elements 50 to perform a function of rotatably supporting a wheel of a vehicle to a vehicle body, and a constant velocity joint 60 is coupled to one side of a wheel bearing to transmit power generated from a driving device to the wheel bearing.

The constant velocity joint 60 may be configured to have a structure in which rolling members 80 (for example, ball members) and an inner member 90 (inner race) are accommodated in an outer member 70 (outer race) and a central axis 92 connected to the driving device is coupled to the inner member 90. The outer member 70 may comprise a stem portion 72 provided to extend in an axial direction on an outer axial end portion thereof. Splines formed on an outer circumferential surface of the stem portion 72 are engaged with splines formed on an inner circumferential surface of the wheel hub 20. The outer member 70 of the constant velocity joint 60 may be configured such that an outer axial end surface of a shoulder portion 74 is in contact with an inner axial end surface of the wheel hub 20 or the inner ring 30.

In the wheel bearing assembly configured as above, when relative movement is generated between contact surfaces due to a large torque load, friction and/or noise may occur at a contact surface (metal contact surface between steels) between the outer member 70 of the constant velocity joint 60 and the wheel hub 20 or the inner ring 30.

In order to solve such a matter, there is proposed a technique in which a washer member is mounted on the contact surface between the outer member 70 of the constant velocity joint 60 and the wheel hub 20 or the inner ring 30. However, in such a structure in which the washer member is mounted, a process of assembling the wheel bearing assembly may become complicated and damage may occur in the wheel hub 20 or the inner ring 30 when mounting the washer member in a press-fitting manner. Additionally, the washer introduces additional distance between contact surfaces reducing overall stiffness of the connection.

### SUMMARY

### Technical Goals

The present invention was made to solve the above-mentioned matters, and the present invention is for the purpose of providing a wheel bearing assembly for a vehicle which is configured to suppress stick-slip noise from being generated at a contact surface between a wheel bearing and a constant velocity joint by applying a low-friction metal alloy coating layer on the contact surface between the wheel bearing and the constant velocity joint to change frictional forces at the contact surface.

### Technical Solutions

Representative configurations of the present invention to achieve the above aspects are as follows.

According to an example embodiment of the present invention, there is provided a wheel bearing assembly for rotatably mounting and supporting a wheel of a vehicle on a vehicle body. According to an example embodiment of the present invention, the wheel bearing assembly may comprise: a wheel hub to which the wheel of the vehicle is mounted and configured to rotate together with the wheel of the vehicle; at least one inner ring mounted on an outer circumferential surface of the wheel hub in a press-fitting manner; an outer ring mounted on and fixed to a vehicle-body-side member; a plurality of rolling elements configured to rotatably support the wheel hub and the inner ring relative to the outer ring; and a constant velocity joint coupled to the wheel hub. According to an example embodiment of the present invention, the constant velocity joint may be configured such that an outer axial end surface of a shoulder portion is in contact with an inner axial end surface of the wheel hub or the inner ring, and a low-friction metal alloy layer may be provided on one side of a contact surface between the outer axial end surface of the shoulder portion of the constant velocity joint and the inner axial end surface of the wheel hub or the inner ring.

According to an example embodiment of the present invention, the low-friction metal alloy layer may be provided on the outer axial end surface of the shoulder portion of the constant velocity joint.

According to an example embodiment of the present invention, the low-friction metal alloy layer may be provided on the inner axial end surface of the wheel hub.

According to an example embodiment of the present invention, the inner ring may be configured to be fixed by an orbital forming portion formed by plastically deforming an inner axial end portion of the wheel hub in a radially outward direction, and the low-friction metal alloy layer may be provided on an inner axial end surface of the orbital forming portion of the wheel hub.

According to an example embodiment of the present invention, the low-friction metal alloy layer may be provided on the inner axial end surface of the inner ring.

According to an example embodiment of the present invention, the low-friction metal alloy layer may be formed of a bronze alloy.

According to an example embodiment of the present invention, the low-friction metal alloy layer may be formed of a lead-free tin bronze alloy.

According to an example embodiment of the present invention, the low-friction metal alloy layer may be configured to entirely or partially cover the axial contact surface between the shoulder portion of the constant velocity joint and the wheel hub or the inner ring.

According to an example embodiment of the present invention, the low-friction metal alloy layer may be formed to have an axial thickness of 0.005 mm to 0.5 mm.

According to an example embodiment of the present invention, the low-friction metal alloy layer may be formed to have a hardness of 70 HV to 250 HV.

According to an example embodiment of the present invention, the low-friction metal alloy layer may be formed through a cold spray coating.

According to an example embodiment of the present invention, the low-friction metal alloy layer may be formed through a laser metal deposition.

According to an example embodiment of the present invention, the low-friction metal alloy layer may be formed through high-speed laser material deposition.

According to an example embodiment of the present invention, the low-friction metal alloy layer may be formed through electroplating.

In addition, the wheel bearing assembly for a vehicle according to the present invention may further comprise other additional configurations to the extent that it does not harm the technical idea of the present invention.

### Technical Effects

A wheel bearing assembly for a vehicle according to an example embodiment of the present invention is configured such that a low-friction metal alloy layer is formed on a contact surface between a wheel bearing and a constant velocity joint, which makes it possible to suppress frictional noise from being generated at the contact surface between the wheel bearing and the constant velocity joint (contact surface between steels).

Further, the wheel bearing assembly for a vehicle according to an example embodiment of the present invention is configured such that the above-described low-friction metal alloy layer is formed of a bronze alloy. This makes it possible to easily form the low-friction metal alloy layer having an excellent wear resistance and corrosion resistance while more effectively preventing the generation of stick-slip noise, without any damage.

Further, the wheel bearing assembly for a vehicle according to an example embodiment of the present invention is configured such that the low-friction metal alloy layer is formed through high-speed laser material deposition (EHLA) or the like. This makes it possible to form the low-friction metal alloy layer having a sufficient thickness at a high speed while minimizing the generation of heat on a base material.

Further, low thickness of the added layer allows to apply the solution without significant changes to existing connection geometry. This makes it possible to keep main characteristics of the connection unchanged.

### BRIEF DESCRIPTION OF THE DRAWINGS

FIG. 1 exemplarily illustrates an example of a wheel bearing assembly for a vehicle (a wheel bearing assembly of a third-generation structure).

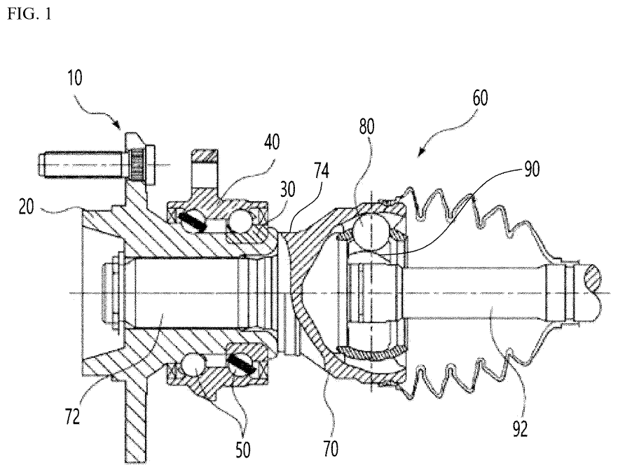

FIG. 2 exemplarily illustrates an overall structure of a wheel bearing assembly for a vehicle according to an example embodiment of the present invention.

FIG. 3 exemplarily illustrates a cross-sectional structure of the wheel bearing assembly for a vehicle according to an example embodiment of the present invention, in which only an outer member of a constant velocity joint is illustrated for the sake of convenience in illustration.

FIG. 4 exemplarily illustrates a state where the constant velocity joint is omitted in the wheel bearing assembly for a vehicle according to an example embodiment of the present invention.

FIG. 5 exemplarily illustrates a cross-sectional structure of a wheel bearing assembly for a vehicle according to another example embodiment of the present invention.

### EXPLANATION OF REFERENCE NUMERALS

100: Wheel bearing assembly
200: Wheel hub
210: Wheel mounting flange
220: Forming portion
300: Inner ring
400: Outer ring
410: Vehicle-body-side mounting flange
500: Rolling element
600: Constant velocity joint
610: Outer member
620: Shoulder portion
630: Stem portion
700: Low-friction metal alloy layer

### DETAILED DESCRIPTION

Example embodiments of the present invention described herein are exemplified for the purpose of describing the technical spirit of the present invention. The scope of the present invention is not limited to the example embodiments described below or to detailed descriptions of these example embodiments.

Unless otherwise defined, all technical and scientific terms used herein have the same meaning commonly understood by those skilled in the art to which the present invention pertains. All terms used herein are selected for the purpose of more clearly describing the present invention and not limiting the scope of the present invention defined by appended claims.

Unless the phrase or sentence clearly indicates otherwise, terms “comprising,” “including,” “having,” and the like used herein should be construed as open-ended terms encompassing the possibility of including other example embodiments.

The term “axial direction” used herein may be defined as a direction extending along a rotational central axis of a wheel bearing. The term “radial direction” used herein may be defined as a direction perpendicular to the axial direction and away from the rotational central axis or approaching the rotational central axis. The term “circumferential direction” used herein may be defined as a direction rotating about the axial direction described above.

Unless the phrase or sentence clearly indicates otherwise, the expression “a constituent element extends in the axial direction or the radial direction” used herein should be understood as encompassing a case where the constituent element extends parallel to the axial direction or the radial direction as well as a case where the constituent element extends obliquely with respect to the axial direction or the radial direction.

The singular form described herein may include the plural form unless the context clearly dictates otherwise, and this is equally applied to the singular form set forth in the claims.

Throughout the present specification, when a constituent element is referred to as being “positioned” at or “formed” on one side of another constituent element, the constituent element may be in direct contact with or directly formed on the one side of another constituent element, or may be positioned at or formed on another constituent element by intervening yet another constituent element therebetween.

Hereinafter, example embodiments of the present invention will be described in detail with reference to the accompanying drawings at such an extent that they may be readily practiced by those ordinary skilled in the art. In the accompanying drawings, the same reference numerals are assigned to the same or corresponding components. Further, in the following descriptions of the example embodiments, duplicate descriptions of the same or corresponding constituent elements may be omitted. However, even though a description(s) of any constituent element is omitted, such a constituent element is not intended to be excluded in any example embodiment.

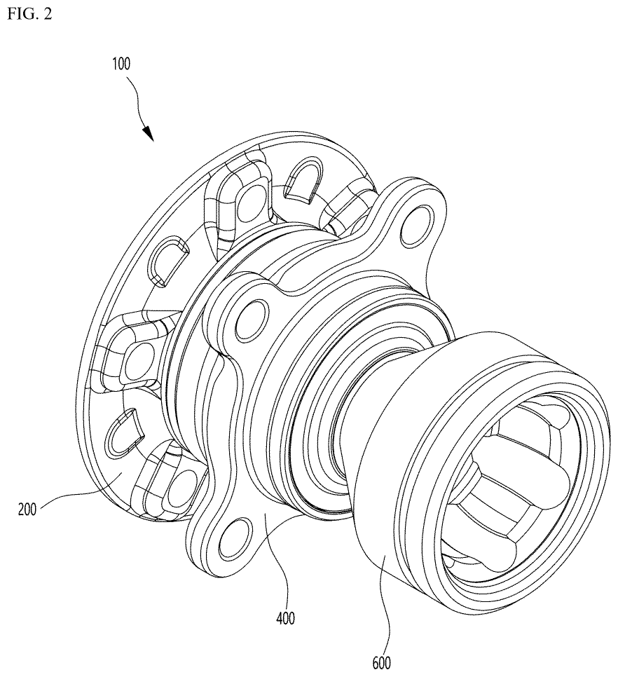

Referring to FIGS. 2 to 5, there are exemplarily illustrated a wheel bearing assembly 100 for a vehicle according to an example embodiment of the present invention. As illustrated in the drawings, the wheel bearing assembly 100 according to an example embodiment of the present invention may be configured such that rotary elements (for example, a wheel hub 200 and an inner ring 300) are connected to a non-rotary element (for example, an outer ring 400) via rolling elements 500 to perform a function of rotatably supporting a wheel of the vehicle to a vehicle body, like a conventional wheel bearing assembly for a vehicle.

According to an example embodiment of the present invention, the wheel hub 200 may be formed to have a generally cylindrical structure extending in an axial direction, and may be configured such that a wheel mounting flange (hub flange) 210 is provided on an outer circumferential surface of one side of the wheel hub 200. The wheel mounting flange 210 may be formed in a shape extending in a radially outward direction from the outer circumferential surface of the wheel hub 200 to mount the wheel of the vehicle to the wheel hub 200 by hub bolts or the like. Further, an inner ring 300 may be mounted on a vehicle-body-side end portion of the wheel hub 200. A portion of the outer circumferential surface of the wheel hub 200 may be formed with a raceway (inner raceway) for the rolling elements 500 to support the rolling elements 500 at a radially inward position.

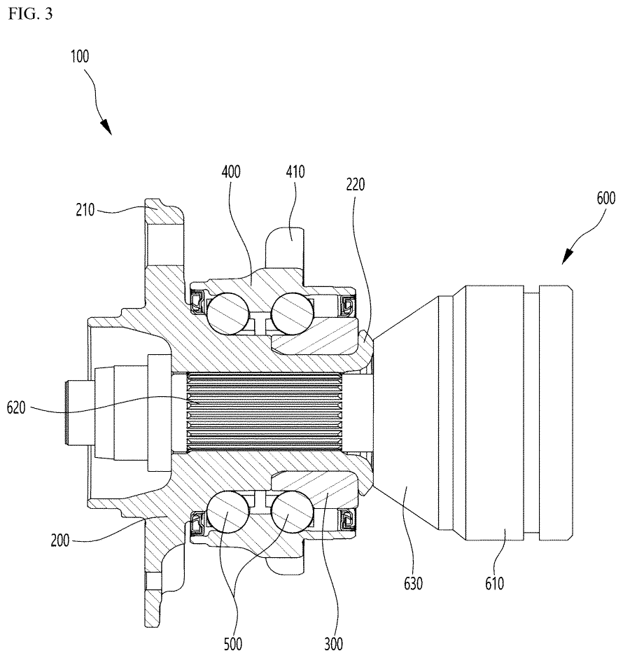

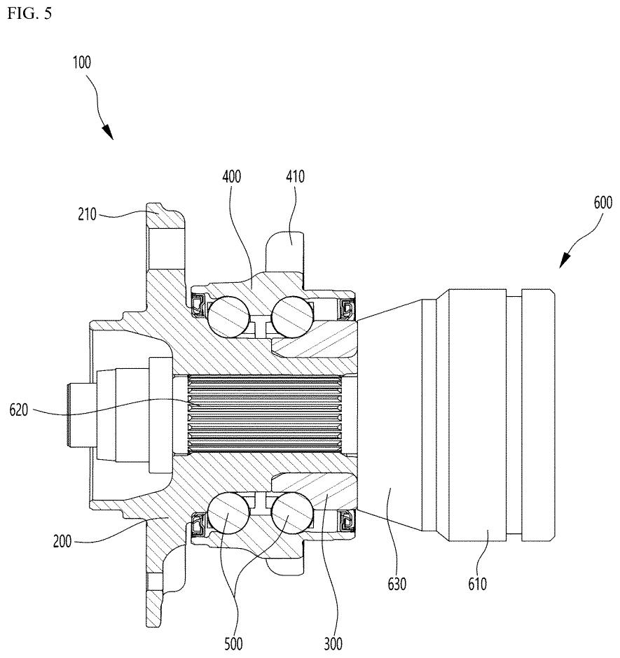

According to an example embodiment of the present invention, one or more inner rings 300 may be mounted on the outer circumferential surface of the wheel hub 200. An outer circumferential surface of the inner ring 300 may have a raceway (inner raceway) for the rolling elements 500 to support the rolling elements 500 at a radially inward position. For example, the inner ring 300 may be coupled to a seat portion provided near the vehicle-body-side end portion of the wheel hub 200 in a press-fitting manner, and may be fixed to the wheel hub 200 in a state where a predetermined preload is applied. For example, as illustrated in FIG. 3, the inner ring 300 may be supported on and fixed to the wheel hub 200 by an orbital forming portion 220 formed by plastically deforming an inner axial end portion of the wheel hub 200 in the radially outward direction. However, the present invention is not limited thereto, but may be modified to other various configurations. For example, as illustrated in FIG. 5, the inner ring 300 is supported on and fixed to the wheel hub 200 in a state where an inner axial end surface of the inner ring 300 is in contact with a constant velocity joint 600.

According to an example embodiment of the present invention, the outer ring 400 may be configured to have a raceway provided on an inner circumferential surface thereof to be in contact with the rolling elements 500, and may be configured to be mounted on and fixed to a vehicle-body-side member (for example, a chassis member such as a knuckle). For example, as illustrated in the drawings, the outer ring 400 may have a vehicle-body-side mounting flange 410 on an outer circumferential surface thereof, and the outer ring 400 may be mounted to the vehicle-body-side member (for example, a chassis member such a knuckle) via the vehicle-body-side mounting flange 410.

According to an example embodiment of the present invention, the rolling elements 500 are provided between the rotary elements (for example, the wheel hub 200 and/or the inner ring 300) and the non-rotary element (for example, the outer ring 400) of the wheel bearing assembly 100, thus performing a function of rotatably supporting the rotary elements of the wheel bearing assembly 100 relative to the non-rotary element.

However, the above-described configurations of the wheel bearing assembly 100 according to an example embodiment of the present invention are not limited to those illustrated in the drawings, but may be modified to other various configurations.

For example, in the case of the example embodiments illustrated in the drawings, the wheel bearing assembly 100 is configured such that one raceway for supporting the rolling elements 500 is formed directly on the outer circumferential surface of the wheel hub 200. However, the wheel bearing assembly 100 according to an example embodiment of the present invention may be also configured such that two inner rings 300 are mounted on the wheel hub 200 and the rolling elements 500 are supported by the two inner rings 300.

Further, in the case of the example embodiments illustrated in the drawings, the rolling elements 500 are configured as ball members having a spherical shape. However, the rolling elements 500 may be configured as other rolling members having another shape such as a tapered roller and the like.

According to an example embodiment of the present invention, the constant velocity joint 600 is coupled to the wheel hub 200 and power generated from a driving device is transmitted to a wheel bearing via the constant velocity joint 600.

According to an example embodiment of the present invention, similar with a conventional wheel bearing assembly for a vehicle, the constant velocity joint 600 may be configured to have a structure in which rolling members (for example, ball members; not illustrated) and an inner member (inner race; not illustrated) for supporting the rolling members are accommodated in an outer member (outer race) 610, and a central axis connected to the driving device is coupled to the inner member. The outer member 610 of the constant velocity joint 600 may comprise a stem portion 620 provided to extend in the axial direction on an outer axial end portion thereof. Splines formed on an outer circumferential surface of the stem portion 620 are engaged with splines formed on the inner circumferential surface of the wheel hub 200 so that the power is transmitted to the wheel bearing.

According to an example embodiment of the present invention, the constant velocity joint 600 is coupled to the wheel bearing such that one axial end surface of the outer member 610 of the constant velocity joint 600 may be brought into contact with the inner axial end surface of the wheel hub 200 or the inner ring 300 of the wheel bearing.

For example, as illustrated in FIG. 3, the outer member 610 of the constant velocity joint 600 may be configured such that an outer axial end surface of a shoulder portion 630 is in contact with an inner axial end surface of the wheel hub 200, more specifically an inner axial end surface of the orbital forming portion 220 of the wheel hub 200. Alternatively, as illustrated in FIG. 5, the outer member 610 of the constant velocity joint 600 may be configured such that the outer axial end surface of the shoulder portion 630 is in contact with the inner axial end surface of the inner ring 300.

According to an example embodiment of the present invention, a low-friction metal alloy layer 700 may be provided on one side of a contact surface between the shoulder portion 630 of the constant velocity joint 600 and the wheel hub 200 or the inner ring 300.

According to an example embodiment of the present invention, the low-friction metal alloy layer 700 may not be provided on both sides of the contact surface between the constant velocity joint and the wheel bearing, but may be provided on one side of the contact surface.

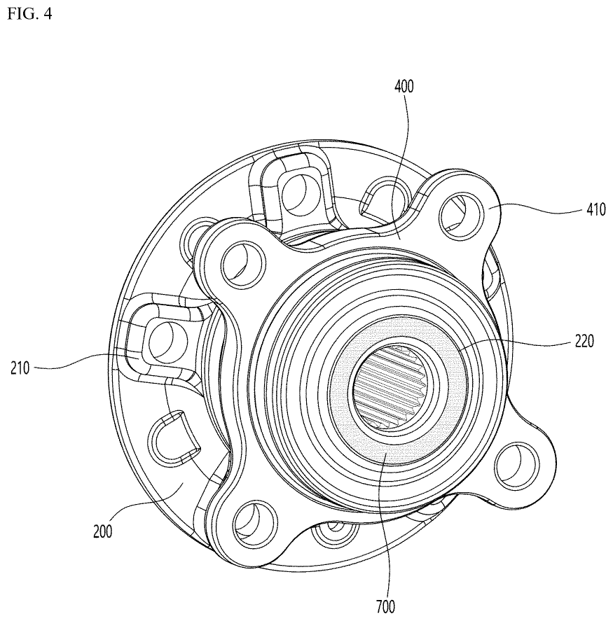

For example, as illustrated in FIG. 4, the low-friction metal alloy layer 700 may be provided on the inner axial end surface of the wheel hub 200 in contact with the shoulder portion 630 of the constant velocity joint 600 [in the case of the example embodiment illustrated in the drawing, the inner axial end surface (the axial contact surface with the constant velocity joint 600) of the orbital forming portion 220 of the wheel hub 200].

Alternatively, the low-friction metal alloy layer 700 may be provided on the outer axial end surface of the shoulder portion 630 of the constant velocity joint 600 in contact with the wheel bearing rather than being provided on the wheel bearing.

Further, when the shoulder portion 630 of the constant velocity joint 600 is mounted on the inner ring 300 as the example embodiment illustrated with reference to FIG. 5, the low-friction metal alloy layer 700 may be provided on the inner axial end surface of the inner ring 300 in contact with the shoulder portion 630 of the constant velocity joint 600.

According to an example embodiment of the present invention, low-friction metal alloy layer 700 may entirely or partially cover the axial contact surface between the shoulder portion 630 of the constant velocity joint 600 and the wheel hub 200 or the inner ring 300.

As described above, the wheel bearing assembly 100 according to an example embodiment of the present invention is configured such that low-friction metal alloy layer 700 is provided on the contact surface between the wheel bearing and the constant velocity joint. This makes it possible to suppress stick-slip noise or the like from being generated at the contact surface between the wheel bearing and the constant velocity joint (contact surface between steels).

According to an example embodiment of the present invention, low-friction metal alloy layer 700 may be formed of a metal material having a relatively low frictional coefficient and a relatively high plasticity to effectively suppress friction and/or noise from occurring at the contact surface between the constant velocity joint 600 and the wheel hub 200 or the inner ring 300.

According to an example embodiment of the present invention, the low-friction metal alloy layer 700 may be formed of a bronze alloy, more preferably a lead-free tin bronze alloy.

The bronze alloy has a property that a difference between a static frictional coefficient and a dynamic frictional coefficient is small. This is advantageous in preventing the stick-slip nose. Further, a melting point of the bronze alloy is low, which makes it possible to form a coating layer without any damage to a steel. In addition, the bronze ally may provide excellent wear resistance and corrosion resistance. Therefore, the bronze alloy may be used advantageously to form the low-friction metal alloy layer 700 according to an example embodiment of the present invention.

According to an example embodiment of the present invention, the low-friction metal alloy layer 700 may be formed to have an axial thickness of 0.005 mm to 0.5 mm.

Further, according to an example embodiment of the present invention, the low-friction metal alloy layer may be formed to have a hardness of 70 HV and 250 HV to suppress damage caused by an axial force, and may be formed to have a tensile strength of 150 N/mm² and 700 N/mm².

According to an example embodiment of the present invention, the low-friction metal alloy layer 700 may be formed through a spraying process such as a cold spray coating, a deposition process such as a laser material deposition or high speed laser material deposition (EHLA), an electroplating, or the like.

According to an example embodiment of the present invention, the low-friction metal alloy layer 700 may preferably be formed through the high speed laser deposition (EHLA).

The high speed laser deposition (EHLA) may form the metal-coated layer with a sufficient thickness at a high speed and may minimize the generation of heat on a base material during the laser deposition. Therefore, by using the high speed laser deposition, it is possible to more easily form the above-described low-friction metal alloy layer 700 on the contact surface between the constant velocity joint and the wheel bearing in a stable manner.

Although the present invention has been described above in terms of specific items such as detailed constituent elements as well as the limited example embodiments and the drawings, they are merely provided to help more general understanding of the present invention, and the present invention is not limited to the above example embodiments. Various modifications and changes could have been realized by those skilled in the art to which the present invention pertains from the above description.

Therefore, the spirit of the present invention need not to be limited to the above-described example embodiments, and in addition to the appended claims to be described below, and all ranges equivalent to or changed from these claims need to be said to belong to the scope and spirit of the present invention.

What is claimed is:

1. A wheel bearing assembly (100) which rotatably mounts and supports a wheel of a vehicle on a vehicle body, the wheel bearing assembly comprising:
a wheel hub (200) on which the wheel of the vehicle is mounted and which is configured to rotate together with the wheel of the vehicle;
at least one inner ring (300) mounted on an outer circumferential surface of the wheel hub (200) in a press-fitting manner;
an outer ring (400) mounted on and fixed to a vehicle-body-side member;
a plurality of rolling elements (500) configured to rotatably support the wheel hub (200) and the inner ring (300) relative to the outer ring (400); and
a constant velocity joint (600) coupled to the wheel hub (200),
wherein the constant velocity joint (600) is configured such that an outer axial end surface of a shoulder portion (630) is in contact with an inner axial end surface of the wheel hub (200) or the inner ring (300), and
wherein a low-friction metal alloy layer (700) is provided on one side of a contact surface between the outer axial end surface of the shoulder portion (630) of the constant velocity joint (600) and the inner axial end surface of the wheel hub (200) or the inner ring (300).

2. The wheel bearing assembly of claim 1, wherein the low-friction metal alloy layer (700) is provided on the outer axial end surface of the shoulder portion (630) of the constant velocity joint (600).

3. The wheel bearing assembly of claim 1, wherein the low-friction metal alloy layer (700) is provided on the inner axial end surface of the wheel hub (200).

4. The wheel bearing assembly of claim 3, wherein the inner ring (300) is configured to be fixed by an orbital forming portion (220) formed by plastically deforming an inner axial end portion of the wheel hub (200) in a radially outward direction, and
wherein the low-friction metal alloy layer (700) is provided on an inner axial end surface of the orbital forming portion (220), which is axial contact surface with the constant velocity joint (600).

5. The wheel bearing assembly of claim 1, wherein the low-friction metal alloy layer (700) is provided on the inner axial end surface of the inner ring (300).

6. The wheel bearing assembly of claim 1, wherein low-friction metal alloy layer (700) is formed of a bronze alloy.

7. The wheel bearing assembly of claim 1, wherein the low-friction metal alloy layer (700) is formed of a lead-free tin bronze alloy.

8. The wheel bearing assembly of claim 1, wherein the low-friction metal alloy layer (700) is configured to entirely or partially cover the axial contact surface between the shoulder portion (630) of the constant velocity joint (600) and the wheel hub (200) or the inner ring (300).

9. The wheel bearing assembly of claim 1, wherein the low-friction metal alloy layer (700) is formed to have an axial thickness of 0.005 mm to 0.5 mm.

10. The wheel bearing assembly of claim 1, wherein the low-friction metal alloy layer (700) is formed to have a hardness of 70 HV to 250 HV.

11. The wheel bearing assembly of claim 1, wherein the low-friction metal alloy layer (700) is formed through cold spray coating.

12. The wheel bearing assembly of claim 1, wherein the low-friction metal alloy layer (700) is formed through laser material deposition.

13. The wheel bearing assembly of claim 1, wherein the low-friction metal alloy layer (700) is formed through high-speed laser material deposition.

14. The wheel bearing assembly of claim 1, wherein the low-friction metal alloy layer (700) is formed through electroplating.
